(19) United States
(12) Patent Application Publication
(10) Pub. No.: US 2020/0337163 A1
(43) Pub. Date: Oct. 22, 2020

(54) DISPLAY DEVICE

(71) Applicants: BEIJING BOE OPTOELECTRONICS TECHNOLOGY CO., LTD., Beijing (CN); BOE TECHNOLOGY GROUP CO., LTD., Beijing (CN)

(72) Inventor: Junhuan LIU, Beijing (CN)

(73) Assignees: BEIJING BOE OPTOELECTRONICS TECHNOLOGY CO., LTD., Beijing (CN); BOE TECHNOLOGY GROUP CO., LTD., Beijing (CN)

(21) Appl. No.: 16/956,841

(22) PCT Filed: Sep. 25, 2019
(86) PCT No.: PCT/CN2019/107721

§ 371 Date: Jun. 22, 2020

(30) Foreign Application Priority Data
Sep. 29, 2018 (CN) 201811146648.4

(51) Int. Cl. H05K 5/02; G09F 9/30; H01L 51/00; H01L 51/52; H05K 5/00

(52) U.S. Cl. CPC H05K 5/0217; G09F 9/301; G09F 9/33; H01L 51/5237; H05K 5/0017; H01L 51/0097

(57) ABSTRACT

A display device includes: a first flexible display screen having a first display surface and a first surface away from the first display surface; a second flexible display screen having a second display surface and a second surface away from the second display surface; a first engagement structure on the first surface; and a second engagement structure on the second surface. The first flexible display screen and the second flexible display screen are fixedly connected via an engagement between the first engagement structure and the second engagement structure.

### CROSS-REFERENCE TO RELATED APPLICATION

The present disclosure claims the benefit and priority of Chinese Application No. 201811146648.4, filed on Sep. 29, 2018, the disclosures of which are incorporated in their entirety by reference herein.

### TECHNICAL FIELD

The present disclosure relates to the field of display technology, and in particular to a display device.

### BACKGROUND

With the development of display technology, flexible display screens have gradually become mainstream products in the display market due to their advantages such as light and thin, small power consumption and wide application scenarios.

Currently, a flexible display device on the market is usually of a single-screen structure due to requirement for fixing a flexible screen, which is difficult to meet needs of three-dimensional display.

### SUMMARY

One embodiment of the present disclosure provides a display device including: a first flexible display screen having a first display surface and a first surface away from the first display surface; a second flexible display screen having a second display surface and a second surface away from the second display surface; a first engagement structure on the first surface; and, a second engagement structure on the second surface. The first flexible display screen and the second flexible display screen are fixedly connected via an engagement between the first engagement structure and the second engagement structure.

Optionally, the first surface and the second surface are oppositely arranged.

Optionally, the first display surface and the second display surface are located two sides of the display device; the first engagement structure and the second engagement structure are located between the first surface and the second surface, and are detachably engaged with each other.

Optionally, the first engagement structure includes a plurality of first meshing teeth; the second engagement structure includes a plurality of second meshing teeth; and, the plurality of the first meshing teeth are engaged with the plurality of second meshing teeth.

Optionally, each of the plurality of first meshing teeth and the plurality of second meshing teeth is a trapezoidal tooth.

Optionally, the first display surface is a curved surface or a planar surface; and the second display surface is a curved surface or a planar surface.

Optionally, each of the first display surface and the second display surface is a planar surface; and an angle between the first display surface and the second display surface is greater than or equal to zero degrees.

Optionally, the first surface is provided with a first flexible protective layer; the second surface is provided with a second flexible protective layer; the plurality of first meshing teeth are provided on the first flexible protective layer; and the plurality of the second meshing teeth are provided on the second flexible protective layer.

Optionally, the display device further includes: a housing having an accommodating space and an opening allowing the accommodating space to communicate with an outside; a first rolling structure and a second rolling structure in the accommodating space. At least one part of the first flexible display screen is wound on the first rolling structure; at least one part of the second flexible display screen is wound on the second rolling structure; an end of the first flexible display screen away from the first rolling structure extends to the opening; an end of the second flexible display screen away from the second rolling structure extends to the opening; the first rolling structure drives the first flexible display screen to extend out of or retract into the accommodating space of the housing through the opening; the second rolling structure drives the second flexible display screen to extend out of or retract into the accommodating space of the housing through the opening; the first engagement structure in the accommodating space and the second engagement structure in the accommodating space are separated from each other; the first engagement structure and the second engagement structure, which extend out of the accommodating space through the opening, are engaged with each other.

One embodiment of the present disclosure provides a display device including: a housing having an accommodating space and an opening allowing the accommodating space to communicate with an outside; a first rolling structure and a second rolling structure in the accommodating space; a first flexible display screen having a first display surface and a first surface away from the first display surface; a second flexible display screen having a second display surface and a second surface away from the second display surface; a first engagement structure on the first surface; and a second engagement structure on the second surface. At least one part of the first flexible display screen is wound on the first rolling structure, and an end of the first flexible display screen away from the first rolling structure extends to the opening; at least one part of the second flexible display screen is wound on the second rolling structure, and an end of the second flexible display screen away from the second rolling structure extends to the opening; the first flexible display screen is driven to extend out of the housing through the opening; the second flexible display screen is driven to extend out of the housing through the opening; portions of the first flexible display screen and the second flexible display screen, that extend out of the accommodating space through the opening, are fixedly connected via an engagement between the first engagement structure and the second engagement structure.

Optionally, the first engagement structure includes a plurality of first meshing teeth; the second engagement structure includes a plurality of second meshing teeth; and, the plurality of the first meshing teeth are engaged with the plurality of second meshing teeth.

Optionally, each of the plurality of first meshing teeth and the plurality of second meshing teeth is a trapezoidal tooth.

Optionally, through rotation of the first rolling structure and the second rolling structure, the first flexible display screen and the second flexible display screen have a first state in which a portion that extends out of the housing through the opening is gradually increased, and a second state in which the portion that extends out of the housing through the opening is gradually decreased; in the first state and the second state, the first engagement structure and the second engagement structure, which are on the first flexible display screen and the second flexible display screen and located within the accommodating space, are separated from each other; the first engagement structure and the second engagement structure, which extend out of the housing through the opening, engage with other.

Optionally, the display device further includes a meshing separator disposed within the accommodating space; the meshing separator is configured to, in the second state, when the first flexible display screen and the second flexible display screen move into the accommodating space from the outside of the housing, separate the first engagement structure and the second engagement structure which are engaged with each other, from each other at the opening.

Optionally, the display device further includes a fixing structure located outside of the housing; the end of the first flexible display screen away from the first rolling structure is connected with the fixing structure; the end of the second flexible display screen away from the second rolling structure is connected with the fixing structure; when the fixing structure is applied with a pulling force away from the opening, the first rolling structure and the second rolling structure are driven to rotate by the first flexible display screen and the second flexible display screen, respectively, thereby enabling the first flexible display screen and the second flexible display screen to be in the first state.

Optionally, the display device further includes: a self-locking structure configured to lock the first rolling structure and the second rolling structure, thereby keeping the portions of the first flexible display screen and the second flexible display screen, that extend out of the housing through the opening, unchanged; a control button coupled with the self-locking structure and configured to switch the self-locking structure between a state of locking the first rolling structure and the second rolling structure and a state of unlocking the first rolling structure and the second rolling structure.

Optionally, the display device further includes an elastic element disposed on each of the first rolling structure and the second rolling structure; the elastic element is configured to, when the pulling force on the fixing structure disappears, under action of elastic force, drive the first rolling structure and the second rolling structure to rotate, thereby enabling the first flexible display screen and the second flexible display screen to be in the second state.

Optionally, each of the first rolling structure and the second rolling structure includes a rolling wheel; the self-locking structure includes a ratchet wheel provided coaxially with the rolling wheel, and a pawl in engagement with the ratchet.

Optionally, the first surface is provided with a first flexible protective layer; the second surface is provided with a second flexible protective layer.

Optionally, a flexible protective layer is provided on a tooth end surface of each of the plurality of first meshing teeth and the plurality of second meshing teeth.

Optionally, a first guide surface and a second guide surface are defined in the housing at the opening; the first guide surface and the second guide surface are parallel to each other; the first flexible display screen and the second flexible display screen respectively abut the first guide surface and the second guide surface when the first flexible display screen and the second flexible display screen extend out of the housing through the opening.

### BRIEF DESCRIPTION OF THE DRAWINGS

FIG. 1 is a first schematic cross-sectional view of a display device according to some embodiments of the present disclosure;

FIG. 2 is a second schematic cross-sectional view of a display device according to some embodiments of the present disclosure;

FIG. 3 is a third schematic cross-sectional view of a display device according to some embodiments of the present disclosure;

FIG. 4 is a schematic cross-sectional view of a display device according to some embodiments of the present disclosure;

FIG. 5 is a schematic diagram of a self-locking structure according to some embodiments of the present disclosure; and

FIG. 6 is a schematic cross-sectional view of a display device according to some embodiments of the present disclosure.

### DETAILED DESCRIPTION

To make the technical problems to be solved, technical solutions and advantages of the present disclosure more apparent, the present disclosure will be described in further detail with reference to the accompanying drawings.

A flexible display device in the related art is usually of a single-screen structure due to requirement for fixing a flexible screen, which is difficult to meet needs of three-dimensional display. For example, a rollable flexible display screen includes a housing with an accommodating space, and a display screen accommodated in the housing. The display screen can be pulled out from the housing and fixed to realize image display. The flexible display screen of the above structure needs to engage with an additional structure for fixing the pull-out flexible screen, thus it is mostly a single-sided display, which is inconvenient to use. Further, this type of rollable flexible display screen is usually only suitable for single-screen two-dimensional display.

In view of this, in order to solve the problem that the flexible display device in the related art is usually only be designed for single-sided display due to requirement for fixing the flexible screen, which is difficult to meet needs of three-dimensional display, one embodiment of the present disclosure provides a display device, in which an engagement structure is provided on a surface of a flexible display screen away from a display surface, and a fixed connection between the two flexible display screens is achieved through engagement of the engagement structures of the two flexible display screens. When the engagement structures of the two flexible display screens are in engagement, the surfaces of the two flexible display screens away from the display surfaces are arranged oppositely, and thus the display surfaces of the two flexible display screens are oriented towards different directions, so that the stereoscopic display of the display device is realized and then the stereoscopic display requirements of the flexible display screen are satisfied.

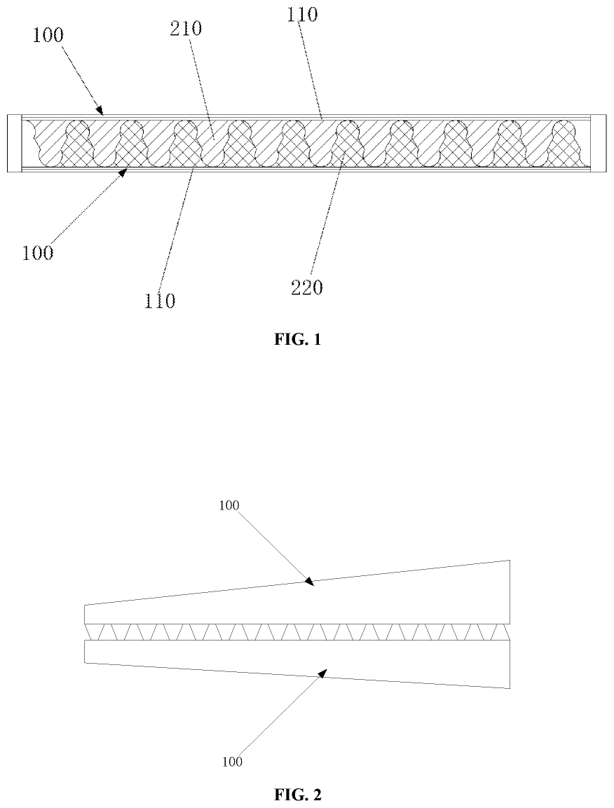

FIG. 1 is a schematic cross-sectional view of a display device according to some embodiments of the present disclosure. Specifically, as shown in FIG. 1, the display device includes:

two flexible display screens 100, a first engagement structure 210 provided on a surface (also referred to as a first surface) away from a display surface (also referred to as a first display surface) of one flexible display screen (also referred to as a first flexible display screen) of the two flexible display screens 100, a second engagement structure 220 provided on a surface (also referred to as a second surface) away from a display surface (also referred to as a second display surface) of the other flexible display screen (also referred to as a second flexible display screen). The second engagement structure 220 is engaged with the first engagement structure 210.

The surfaces of the two flexible display screens 100 away from the display surfaces are oppositely arranged, and the two flexible display screens 100 are fixedly connected through engagement of the first engagement structure 210 and the second engagement structure 220.

In one embodiment of the present disclosure, in a displaying state, the two flexible display screens 100 are fixed through engagement of the first engagement structure 210 and the second engagement structure 220. Then, the two flexible display screens 100 provide a three-dimensional display, thereby satisfying needs of three-dimensional display.

Optionally, as shown in FIG. 1, when the two flexible display screens 100 are fixed through engagement of the first engagement structure 210 and the second engagement structure 220, the display surfaces of the two flexible display screens 100 each may be planar. Optionally, the planar display surfaces of the two flexible display screens 100 may be parallel to each other, thereby forming a three-dimensional device with the display surfaces of the two display screens oriented towards opposite directions. Optionally, as shown in FIG. 2, an included angle greater than zero degrees may be defined between the planar display surfaces of the two flexible display screens 100, thereby forming a three-dimensional device with the display surfaces of the two display screens oriented different directions and with a preset included angle defined between the display surfaces of the two display screens.

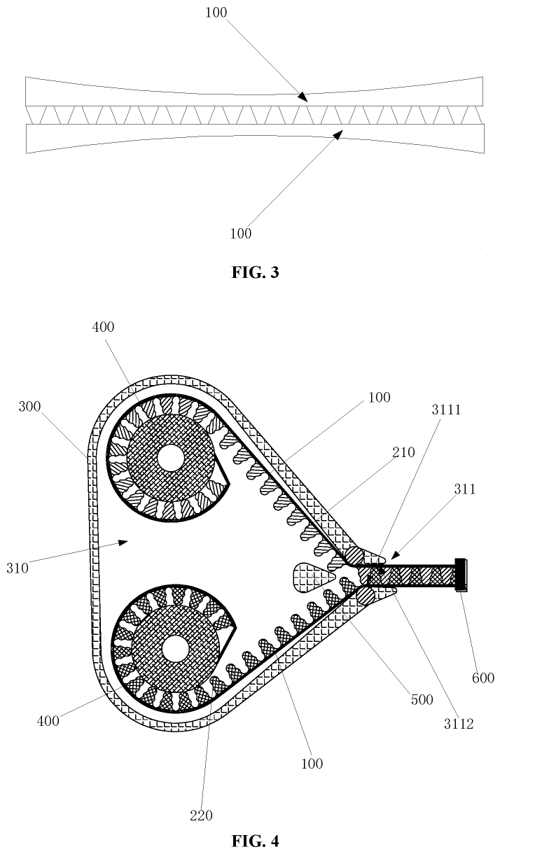

Optionally, as shown in FIG. 3, when the two flexible display screens 100 are fixed through engagement of the first engagement structure 210 and the second engagement structure 220, the display surfaces of the two flexible display screens 100 each may be curved, or one display surface is curved while one display surface is planar, thereby forming a three-dimensional device including a curved display screen.

In one embodiment of the present disclosure, the surfaces of the two flexible display screens 100 away from the display surfaces each are provided with a plurality of meshing teeth. As shown in FIG. 1, the first engagement structure 210 includes a plurality of first meshing teeth and the second engagement structure 220 includes a plurality of second meshing teeth. The first engagement structure 210 and the second engagement structure 220 are connected via engagement between the plurality of first meshing teeth and the plurality of second meshing teeth. Optionally, the first meshing teeth and the second meshing teeth have the same shape and size.

In the display device according to one embodiment of the present disclosure, a plurality of meshing teeth are provided on the surface of the flexible display screen 100 away from the display surface, and a fixed connection between the two flexible display screens 100 is achieved via engagement between the meshing teeth therebetween.

It can be understood that the engagement between the first engagement structure 210 and the second engagement structure 220 may be implemented in other ways and is not limited to meshing teeth.

Further, some embodiments of the present disclosure further provide a display device capable of fixing a rollable flexible display screen for stereoscopic display.

As shown in FIG. 4, a display device according to some embodiments of the present disclosure includes:

a housing 300 having an accommodating space 310 and an opening 311 that allows the accommodating space 310 to communicate with an outside;

two rolling structures 400 (which may be referred to as a first rolling structure and a second rolling structure, respectively) disposed in the accommodating space 310, where each rolling structure 400 is connected with a flexible display screen 100, and an end of the flexible display screen 100 distal to the correspondingly connected rolling structure 400 extends to the opening 311; through the rolling structure 400, the end of each flexible display screen 100 distal to the correspondingly connected rolling structure 400 can extend outside of the housing 300 through the opening 311, thereby enabling at least one part of a display surface of the flexible display screen 100 to be exposed;

a first engagement structure 210 provided on a surface away from a display surface of one of two flexible display screens 100, a second engagement structure 220 provided on a surface away from a display surface of the other one of the two flexible display screens 100, where the second engagement structure 220 is engaged with the first engagement structure 210; when the end of each of the two flexible display screens 100 distal to the correspondingly connected rolling structure 400 extends outside of the housing 300 through the opening 311, the surfaces of the two flexible display screens 100 away from the display surfaces are oppositely arranged, and the two flexible display screens 100 are fixedly connected through engagement of the first engagement structure 210 and the second engagement structure 220.

In the display device of the above embodiment of the present disclosure, by connecting each flexible display screen 100 to one rolling structure 400, the flexible display screen 100 can be moved toward the outside of the housing 300 so that an exposed portion of the display surface increases. Further, a fixed connection between exposed portions of the two flexible display screens 100 outside the housing 300 can be realized by engagement of the first engagement structure 210 and the second engagement structure 220 which are provided on the surfaces of the two flexible display screens 100 away from the display surfaces, respectively. In this way, the exposed portions of the two flexible display screens 100 outside the housing 300 can support each other and will not deform, thereby fixing the flexible display screens and satisfying needs of stereoscopic display.

Optionally, as shown in FIG. 4, when the exposed portions of the two flexible display screens 100 outside the housing 300 are fixed via engagement of the first engagement structure 210 and the second engagement structure 220, the display surfaces of the exposed portions of the two flexible display screens 100 outside the housing 300 each may be planar. Optionally, the planar display surfaces of the two flexible display screens 100 may be parallel to each other, thereby forming a stereoscopic device with the display surfaces of the two display screens oriented towards opposite directions.

In one embodiment of the present disclosure, each of the surfaces of the two flexible display screens 100 away from the display surfaces is provided with a plurality of meshing teeth. As shown in FIG. 4, the first engagement structure 210 includes a plurality of first meshing teeth, and the second engagement structure 220 includes a plurality of second meshing teeth. The plurality of first meshing teeth and the plurality of second meshing teeth engage with each other, so that the first engagement structure 210 is mated with the second engagement structure 220. Optionally, the first meshing teeth and the second engagement structure 220 have the same shape and size.

In addition, in one embodiment of the present disclosure, the two rolling structures 400 can rotate synchronously around their respective axes. Through the synchronous rotation of the two rolling structures, the two flexible display screens 100 has a first state in which a portion that extends through the opening 311 to the outside of the housing 300 is gradually increased, and a second state in which the portion that extends through the opening 311 to the outside of the housing 300 is gradually decreased.

In the first state and the second state, the first engagement structure 210 and the second engagement structure 220, which are on the two flexible display screens 100 and located within the accommodating space 310, are separated from each other. Portions of the first engagement structure 210 and the second engagement structure 220, which extend through the opening 311 to the outside of the housing 300, engage with other.

According to FIG. 4, since the two flexible display screens 100 respectively extend from different positions with respect to the two rolling structures 400, it can be understood that when the two rolling structures 400 rotate synchronously around their respective axes so that the two flexible display screens 100 are in the first state or the second state, rotation directions of the two rolling structures are opposite. Of course, such structure is only one of the ways for moving the two flexible display screens 100, and the specific implementation is not limited to this.

Specifically, as shown in FIG. 4 and FIG. 6, in one embodiment of the present disclosure, each rolling structure 400 includes a rolling wheel 410. The flexible display screen 100 is connected to the rolling wheel 410 and can be wound around the rolling wheel 410.

Referring to FIG. 4 and FIG. 6, when the rolling wheel 410 of the rolling structure 400 rotates clockwise or counterclockwise around the axis 430, the flexible display screen 100 connected to the rolling wheel moves in a direction of extending out of the housing 300, so that a display area of the flexible display screen 100 exposed outside the housing 300 is increased, or, the flexible display screen 100 connected to the rolling wheel moves in a direction of moving into an interior of the housing 300, so that the display area of the flexible display screen 100 exposed outside the housing 300 is decreased.

Based on the above principles, by simultaneous rotation of the rolling wheels in the two rolling structure 400, the two flexible display screens 100 can be simultaneously moved in the direction of extending out of the housing 300, or the two flexible display screens 100 can be simultaneously moved in the direction of moving into the interior of the housing 300.

Further, based on the above control method, as shown in FIG. 4, during synchronous movement of the two flexible display screens 100 in the direction of extending out of the housing 300, under the squeezing action of the opening 311, the meshing teeth on the two flexible display screens 100 are gradually changed from being separated to being engaged with each other when the meshing teeth pass through the opening 311, thereby achieving the fixation of the exposed portions of the two flexible display screens 100 outside the housing 300. During synchronous movement of the two flexible display screens 100 in the direction of moving into the interior of the housing 300, the meshing teeth on the two flexible display screens 100 are gradually changed from being engaged with each other to being separated when the meshing teeth pass through the opening 311, so that the separated flexible display screens 100 can be wound around the corresponding rolling wheels 410, respectively.

Optionally, in one embodiment of the present disclosure, each of the rolling structures 400 may be coupled to a controller, and the two rolling structures 400 are separately controlled to achieve simultaneous rotation. The rolling structures 400 may also be coupled to an identical controller, and the rolling structures 400 may controlled by the identical controller to achieve simultaneous rotation. In addition, optionally, diameters of the rolling wheels of the two rolling structures 400 may be the same, and the synchronous movement of the two flexible display screens 100 can be achieved by synchronous rotation of the two rolling wheels. Of course, diameters of the rolling wheels of the two rolling structures 400 may be also be different, as long as rotation rates of the two rolling wheels are controlled to match, the two flexible display screens 100 can be moved synchronously.

In one embodiment of the present disclosure, as shown in FIG. 4, the display device further includes a meshing separator 500 disposed within the accommodating space 310. The meshing separator 500 is configured to, at the second state, when the two flexible display screens 100 move into the interior of the accommodating space 310 from the outside of the housing 300, separate the first engagement structure 210 and the second engagement structure 220 which are engaged with each other, from each other at the opening 311.

Referring to FIG. 4, in one embodiment of the present disclosure, the meshing separator 500 may be fixed inside the housing 300 and located between the two flexible display screens 100 at the opening 311. Optionally, a cross section of the meshing separator 500 is a triangular, including a tip portion. The tip portion is oriented towards the opening 311, and is configured to, when the two flexible display screens 100 move into the interior of the accommodating space 310 from the outside of the housing 300, separate the meshing teeth which are engaged with each other, from each other.

In one embodiment of the present disclosure, optionally, the display device further includes a fixing structure 600 located outside of the housing 300. The end of each flexible display screen 100 distal to the correspondingly connected rolling structure 400 is connected with the fixing structure 600.

When the fixing structure 600 is applied with a pulling force away from the opening 311, the two rolling structure 400 can be driven to rotate synchronously around their axes through the flexible display screens 100, and portions of the two flexible display screens 100 exposed outside the housing 300 through the opening 311 are gradually increased.

In the display device of the above structure, the fixing structure 600 is disposed on the end of each flexible display screen 100 distal to the correspondingly connected rolling structure 400. A pulling force can be applied on the flexible display screens 100 through the fixing structure 600, so that when the flexible display screen 100 is rolled into the interior of the housing 300, the flexible display screens 100 are pulled outward to drive the rolling structures 400 to rotate, thereby enabling the flexible display screens 100 to extend out of the housing 300.

Optionally, a size of the fixing structure 600 is greater than a size of the opening 311, thereby ensuring that when the flexible display screens 100 move toward the inside of the housing 300, the fixing structure 600 will not move into the housing 300.

In one embodiment of the present disclosure, the display device further includes an elastic element disposed on each rolling structure 400. The elastic element is configured to, when the pulling force on the fixing structure 600 disappears, under action of elastic force, drive the rolling structure 400 to rotate around its axis in a second direction.

Specifically, the elastic element may be a spring disposed on the rolling structure 400, for example, disposed on the rolling wheel 410 of the rolling structure 400. When the flexible display screens 100 are pulled through the fixing structure 600, the elastic element is stretched. When the pulling force on the fixing structure 600 disappears and when the flexible display screens 100 need to be retracted into the housing 300, under action of elastic restoring force of the elastic element, the rolling structures 400 are driven to rotate around their axes to move the flexible display screens 100 into the housing 300. In one embodiment, as shown in FIG. 6, the elastic element may be a torsion spring 470 sleeved between the rolling wheel 410 and a rotating shaft 450. One end of the torsion spring 470 is connected to the rolling wheel 410, and the other end of the torsion spring 470 is connected to the rotating shaft 450. When the flexible display screens 100 are pulled through the fixing structure 600, the movement of the flexible display screens 100 drives the rolling wheel 410 to rotate, and then the rotation of the rolling wheel 410 causes the torsion spring 470 to twist and deform. When the pulling force on the fixing structure 600 disappears and when the flexible display screens 100 need to be retracted into the housing 300, under action of elastic restoring force of the torsion spring 470, the rolling structures 400 are driven to rotate around their axes to move the flexible display screens 100 into the housing 300.

In addition, optionally, the display device according to one embodiment of the present disclosure includes:

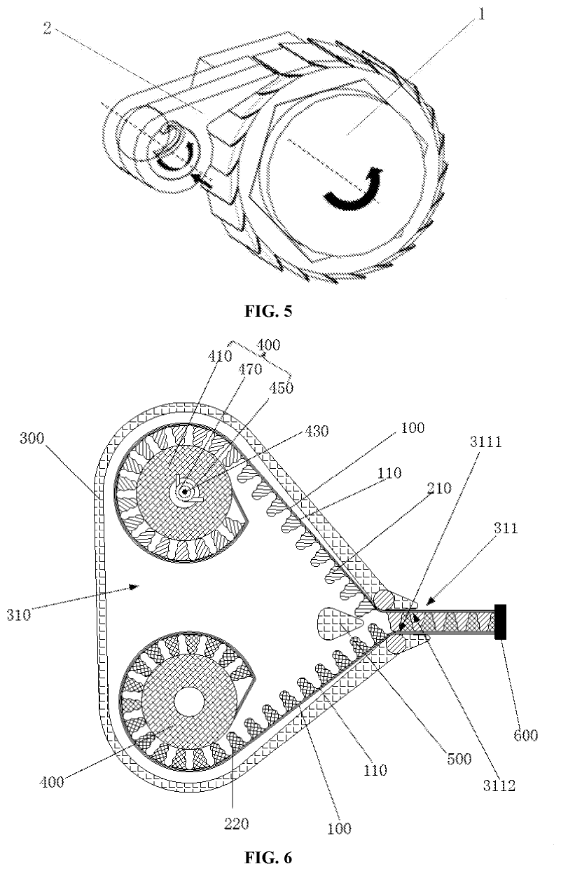

a self-locking structure (as shown in FIG. 5), configured to lock the rolling structure 400, so that the portions of the flexible display screens 100 that extend from the housing 300 remains fixed;

a control button coupled with the self-locking structure and configured to switch the self-locking structure between a state of locking the rolling structure 400 and a state of unlocking the rolling structure.

Optionally, each rolling structure is provided with a self-locking structure. The control button is coupled with each self-locking structure.

By the presence of the above self-locking structure, when the flexible display screens 100 extend from the housing 300 by a certain length, the flexible display screen 100 remains unchanged at this length. For example, when the fixing structure 600 is pulled to extend the flexible display screens 100 by a certain length, after the control button is pressed to cause the self-locking structure in a state of locking the rolling structure 400, the self-locking structure keeps the flexible display screen 100 unchanged at this length after the fixing structure 600 is released. When the control button is pressed to cause the self-locking structure in a state of unlocking the rolling structure 400, under the elastic restoring force of the elastic element, the flexible display screens 100 are moved into the housing 300.

Referring to FIG. 5, in one embodiment of the present disclosure, the self-locking structure may include a ratchet wheel 1 provided coaxially with the rolling wheel, and a pawl 2 in engagement with the ratchet 1. Further, the above the elastic element may be connected to the ratchet 1.

With the above arrangement, when the flexible display screens 100 are pulled through the fixing structure 600, the rolling wheel drives the ratchet wheel 1 to rotate. When the flexible display screens 100 are stopped to be pulled, the pawl 2 is locked between two ratchet teeth of the ratchet 1, i.e., in a state of locking the rolling structure 400, so that the ratchet wheel 1 cannot be driven to rotate under the elastic restoring force of the elastic element, thereby keeping the flexible display screens 100 at a certain position.

In addition, in one embodiment of the present disclosure, the control button may be coupled with a rotation shaft of the pawl 2. By pressing the control button, the pawl 2 is rotated around the rotation shaft to be separated from the ratchet teeth of the ratchet 1, thereby unlocking the rolling structure 400. In this way, under action of the elastic restoring force of the elastic element, the ratchet wheel 1 drives the rolling wheel to rotate, and rotation of the rolling wheel moves the flexible display screens into the housing 300, thereby realizing automatic retraction. Further, when the control button is released, the control button returns to its original position, and then the pawl 2 is rotated around the rotation shaft to be locked between the ratchet teeth of the ratchet wheel 1 gain. Then, the flexible display screens stop the retraction movement, i.e., returning to the state of locking the rolling structure 400.

The above is only one of the implementation structures of the self-locking structure in the embodiment of the present disclosure, which is not limited to this and will not be described in detail here.

In the display device according to one embodiment of the present disclosure, the flexible display screen 100 may be an organic light-emitting diode (OLED) display screen, and the surface away from the display surface is provided with a flexible protective layer 110 (as shown in FIG. 1 and FIG. 6, the flexible protective layer formed on the first flexible display screen provided with the first engagement structure 210 may be referred to as a first flexible protective layer, and the flexible protective layer formed on the second flexible display screen provided with the second engagement structure 220 may be referred to as a second flexible protective layer). Further, the meshing teeth provided on the surface of the flexible display screen 100 away from the display surface may be trapezoidal teeth. When the flexible display screen 100 is wound around the rolling structure 400, the trapezoidal teeth can compensate for empty space generated by winding of flexible display screens. Optionally, a flexible protective layer is further provided on each meshing tooth, thereby ensuring that the trapezoidal teeth do not squeeze the display surface of the flexible display screen 100 when the flexible display screen 100 is wound around the rolling structure 400.

In addition, in one embodiment of the present disclosure, optionally, as shown in FIG. 4, two protruding guide bodies are oppositely arranged on the housing 300 adjacent the opening 311. The two protruding guide bodies define a first guide surface 3111 and a second guide surface 3112, which are parallel to each other and opposite to each other. When the flexible display screens 100 are extended out of or retracted into the housing 300 through the opening 311, the two flexible display screens 100 respectively abut the first guide surface 3111 and the second guide surface 3112, thereby playing a guiding role for the two flexible display screens and then ensuring stability during the movement.

According to the above, in the display device according to some embodiments of the present disclosure, the meshing teeth are provided on the surface of the flexible display screen away from the display surface, and the meshing teeth on the two flexible display screens engage with each other when the two flexible display screens are pulled out from the housing under action of the rolling structure. The engagement between the meshing teeth enables the display surfaces of the flexible display screens to be in a flat state, ensures the fixation of the two rollable flexible display screens and meets stereoscopic display requirements.

The display device based on the above arrangement structure can provide double-sided display with the flexible display screens, provide more display content and viewing angle, and can roll up the flexible display screen, which is convenient to carry and display.

The above are merely the preferred embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure.

1. A display device comprising:
a first flexible display screen having a first display surface and a first surface away from the first display surface;
a second flexible display screen having a second display surface and a second surface away from the second display surface;
a first engagement structure on the first surface; and
a second engagement structure on the second surface;
wherein the first flexible display screen and the second flexible display screen are fixedly connected via an engagement between the first engagement structure and the second engagement structure.

2. The display device according to claim 1, wherein the first surface and the second surface are oppositely arranged.

3. The display device according to claim 2, wherein the first display surface and the second display surface are located two sides of the display device; the first engagement structure and the second engagement structure are located between the first surface and the second surface, and are detachably engaged with each other.

4. The display device according to claim 1, wherein the first engagement structure includes a plurality of first meshing teeth; the second engagement structure includes a plurality of second meshing teeth; and, the plurality of the first meshing teeth are engaged with the plurality of second meshing teeth.

5. The display device according to claim 4, wherein each of the plurality of first meshing teeth and the plurality of second meshing teeth is a trapezoidal tooth.

6. The display device according to claim 4, wherein the first display surface is a curved surface or a planar surface; and the second display surface is a curved surface or a planar surface.

7. The display device according to claim 4, wherein each of the first display surface and the second display surface is a planar surface; and an angle between the first display surface and the second display surface is greater than or equal to zero degrees.

8. The display device according to claim 4, wherein the first surface is provided with a first flexible protective layer; the second surface is provided with a second flexible protective layer; the plurality of first meshing teeth are provided on the first flexible protective layer; and the plurality of the second meshing teeth are provided on the second flexible protective layer.

9. The display device according to claim 1, wherein the display device further includes:
a housing having an accommodating space and an opening allowing the accommodating space to communicate with an outside;
a first rolling structure and a second rolling structure in the accommodating space;
wherein at least one part of the first flexible display screen is wound on the first rolling structure;
at least one part of the second flexible display screen is wound on the second rolling structure;
an end of the first flexible display screen away from the first rolling structure extends to the opening;
an end of the second flexible display screen away from the second rolling structure extends to the opening;
the first rolling structure drives the first flexible display screen to extend out of or retract into the accommodating space of the housing through the opening;
the second rolling structure drives the second flexible display screen to extend out of or retract into the accommodating space of the housing through the opening;
the first engagement structure in the accommodating space and the second engagement structure in the accommodating space are separated from each other;
the first engagement structure and the second engagement structure, which extend out of the accommodating space through the opening, are engaged with each other.

10. A display device comprising:
a housing having an accommodating space and an opening allowing the accommodating space to communicate with an outside;
a first rolling structure and a second rolling structure in the accommodating space;
a first flexible display screen having a first display surface and a first surface away from the first display surface;
a second flexible display screen having a second display surface and a second surface away from the second display surface;
a first engagement structure on the first surface; and
a second engagement structure on the second surface;
wherein at least one part of the first flexible display screen is wound on the first rolling structure, and an end of the first flexible display screen away from the first rolling structure extends to the opening; at least one part of the second flexible display screen is wound on the second rolling structure, and an end of the second flexible display screen away from the second rolling structure extends to the opening; the first flexible display screen is driven to extend out of the housing through the opening; the second flexible display screen is driven to extend out of the housing through the opening;
portions of the first flexible display screen and the second flexible display screen, that extend out of the accommodating space through the opening, are fixedly connected via an engagement between the first engagement structure and the second engagement structure.

11. The display device according to claim 10, wherein the first engagement structure includes a plurality of first meshing teeth; the second engagement structure includes a plurality of second meshing teeth; and, the plurality of the first meshing teeth are engaged with the plurality of second meshing teeth.

12. The display device according to claim 11, wherein each of the plurality of first meshing teeth and the plurality of second meshing teeth is a trapezoidal tooth.

13. The display device according to claim 10, wherein through rotation of the first rolling structure and the second rolling structure, the first flexible display screen and the second flexible display screen have a first state in which a portion that extends out of the housing through the opening is gradually increased, and a second state in which the portion that extends out of the housing through the opening is gradually decreased;
in the first state and the second state, the first engagement structure and the second engagement structure, which are on the first flexible display screen and the second flexible display screen and located within the accommodating space, are separated from each other; the first engagement structure and the second engagement structure, which extend out of the housing through the opening, engage with other.

14. The display device according to claim 13, wherein the display device further includes a meshing separator disposed within the accommodating space; the meshing separator is configured to, in the second state, when the first flexible display screen and the second flexible display screen move into the accommodating space from the outside of the housing, separate the first engagement structure and the second engagement structure which are engaged with each other, from each other at the opening.

15. The display device according to claim 13, wherein the display device further includes a fixing structure located outside of the housing; the end of the first flexible display screen away from the first rolling structure is connected with the fixing structure; the end of the second flexible display screen away from the second rolling structure is connected with the fixing structure;
when the fixing structure is applied with a pulling force away from the opening, the first rolling structure and the second rolling structure are driven to rotate by the first flexible display screen and the second flexible display screen, respectively, thereby enabling the first flexible display screen and the second flexible display screen to be in the first state.

16. The display device according to claim 10, wherein the display device further includes:
a self-locking structure configured to lock the first rolling structure and the second rolling structure, thereby keeping the portions of the first flexible display screen and the second flexible display screen, that extend out of the housing through. the opening, unchanged;
a control button coupled with the self-locking structure and configured to switch the self-locking structure between a state of locking the first rolling structure and the second rolling structure and a state of unlocking the first rolling structure and the second rolling structure.

17. The display device according to claim 15, wherein the display device further includes an elastic element disposed on each of the first rolling structure and the second rolling structure; the elastic element is configured to, when the pulling force on the fixing structure disappears, under action of elastic force, drive the first rolling structure and the second rolling structure to rotate, thereby enabling the first flexible display screen and the second flexible display screen to be in the second state.

18. The display device according to claim 16, wherein each of the first rolling structure and the second rolling structure includes a rolling wheel;
the self-locking structure includes a ratchet wheel provided coaxially with the rolling wheel, and a pawl in engagement with the ratchet.

19. The display device according to claim 10, wherein the first surface is provided with a first flexible protective layer; the second surface is provided with a second flexible protective layer; a flexible protective layer is provided on a tooth end surface of each of the plurality of first meshing teeth and the plurality of second meshing teeth.

20. (canceled)

21. The display device according to claim 10, wherein a first guide surface and a second guide surface are defined in the housing at the opening; the first guide surface and the second guide surface are parallel to each other;
the first flexible display screen and the second flexible display screen respectively abut the first guide surface and the second guide surface when the first flexible display screen and the second flexible display screen extend out of the housing through the opening.
